(19) United States
(12) Patent Application Publication
(10) Pub. No.: US 2007/0155184 A1
(43) Pub. Date: Jul. 5, 2007

(54) Method for producing a nanostructure such as a nanoscale cantilever

(76) Inventors: Sungsoo Yi, Sunnyvale, CA (US); Ying-Lan Chang, Cupertino, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/312,090

(22) Filed: Dec. 20, 2005

(51) Int. Cl. H01L 21/31

(52) U.S. Cl. 438/775

(57) ABSTRACT

Producing a nanostructure, such as a nano-scale cantilever or a nanobridge, involves forming an elevational discontinuity, growing a nanowire that extends out from an upper surface of the elevational discontinuity, and then changing the orientation of the nanowire such that a portion of the nanowire extends above a lower surface of the elevational discontinuity. The orientation of the nanowire can be changed by exposing the nanowire to a flux of ions.

### BACKGROUND OF THE INVENTION

Cantilever-based sensors can be used to detect extremely small displacements. For example, micro-scale cantilevers are being used to produce highly sensitive biological and chemical sensors. In biological and chemical sensing applications, a detection signal is generated in response to a molecular adsorption-induced resonance frequency shift or cantilever bending. To improve the time response and sensitivity of a cantilever-based sensor, it is desirable to reduce the dimensions of the cantilever down to nano-scale dimensions.

Single- or polycrystalline micro-scale cantilevers have been fabricated using known lithographic and wet or dry etching processes. Producing a micro-scale cantilever using known lithographic and wet or dry etching processes involves depositing a thin film of silicon dioxide or silicon nitride on a silicon substrate by chemical vapor deposition (CVD). The thin film is then lithographically patterned such that cantilever shapes are defined on the top surface of the silicon substrate and an etch mask is placed on the bottom surface. A portion of the silicon substrate is then removed by wet or dry etching to produce free-standing cantilevers. This fabrication technique has been used to produce cantilevers with width dimensions on the order of tens of micrometers.

Fabrication techniques based on laser and atomic force microscopy and electron beam lithography have been used to produce cantilevers with width dimensions of less than one micrometer. Fabrication techniques using a focused ion beam (FIB) have been used to produce cantilevers with width dimensions in the 50-500 nm range and thickness dimensions in the 25-100 nm range. FIB fabrication techniques involve using an FIB to reduce the thickness of silicon membranes and then physically cutting out cantilevers from the silicon membranes.

Although some techniques exist for producing cantilevers of various micro- and nano-scale dimensions, decreasing the size of cantilevers to below 50 nm in width remains challenging. Additionally, cantilevers fabricated from silicon dioxide or silicon nitride do not exhibit the most desirable piezoelectric properties for use in highly sensitive sensors.

### SUMMARY OF THE INVENTION

A method for producing a nanostructure, such as a nano-scale cantilever or a nanobridge, involves forming an elevational discontinuity, the elevational discontinuity having an upper surface and a lower surface, growing a nanowire that extends from the upper surface, and then changing the orientation of the nanowire such that a portion of the nanowire extends above the lower surface. In an embodiment, the orientation of the nanowire is changed by exposing the nanowire to a flux of ions.

In another aspect of the invention, a nanostructure, such as a nano-scale cantilever or a nanobridge, is produced by growing a nanowire on a substrate such that the nanowire extends orthogonally from a major surface of the substrate and then changing the orientation of the nanowire to be parallel to the major surface of the substrate. The nanowire is typically formed on the upper surface of an elevational discontinuity on the substrate and near an edge of the elevational discontinuity. Additionally, the location of the nanowire on the upper surface of the elevational discontinuity and the length of the nanowire is such that a portion of the nanowire extends above the lower surface of the elevational discontinuity once the orientation of the nanowire is changed from orthogonal to parallel.

The above-described techniques for producing a nanostructure do not rely on lithography to pattern the nanostructure and therefore are not subject to the size limitations associated with conventional lithography-based fabrications techniques. Nano-scale cantilevers with dimensions as small as 5 nm have been fabricated from compound semiconductor materials using the above-described technique.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1A is a perspective view of a substrate that includes a protruding structure.

FIG. 1B is a side view of FIG. 1A.

FIG. 1C is a side view of a substrate in which the protruding structure is formed from a single step at the surface of the substrate.

FIG. 2A is a perspective view of catalyst nanoparticles deposited on the surface of the protruding structure near an edge.

FIG. 2B is a side view of FIG. 2A.

FIG. 3A is a perspective view of nanowires that are grown orthogonal to the major surface of the substrate.

FIG. 3B is a side view of FIG. 3A.

FIG. 4A is a perspective view of the nanowires of FIG. 3A after the orientation of the nanowires has been changed from orthogonal to the major surface of the substrate to parallel to the major surface of the substrate.

FIG. 4B is a side view of FIG. 4A.

FIGS. 5A and 5B depict two protruding structures that are formed as described above with reference to FIGS. 1A and 1B.

FIGS. 6A and 6B depict catalyst nanoparticles formed on one of the protruding structures as described above with reference to FIGS. 2A and 2B.

FIGS. 7A and 7B depict nanowires grown at the locations of the catalyst nanoparticles as described above with reference to FIGS. 3A and 3B.

FIGS. 8A and 8B depict the nanowires of FIGS. 7A and 7B spanning the trench between the two protruding structures after their orientation has been changed.

FIG. 8C is a side view of a substrate in which a trench is formed below the major surface of the substrate and in which nanowires are re-oriented to span the trench.

FIG. 9 is a process flow diagram of a method for producing a nanostructure.

FIG. 10 is a process flow diagram of another method for producing a nanostructure.

FIG. 11 is a process flow diagram of another method for producing a nanostructure.

Throughout the description similar reference numbers may be used to identify similar elements.

### DETAILED DESCRIPTION

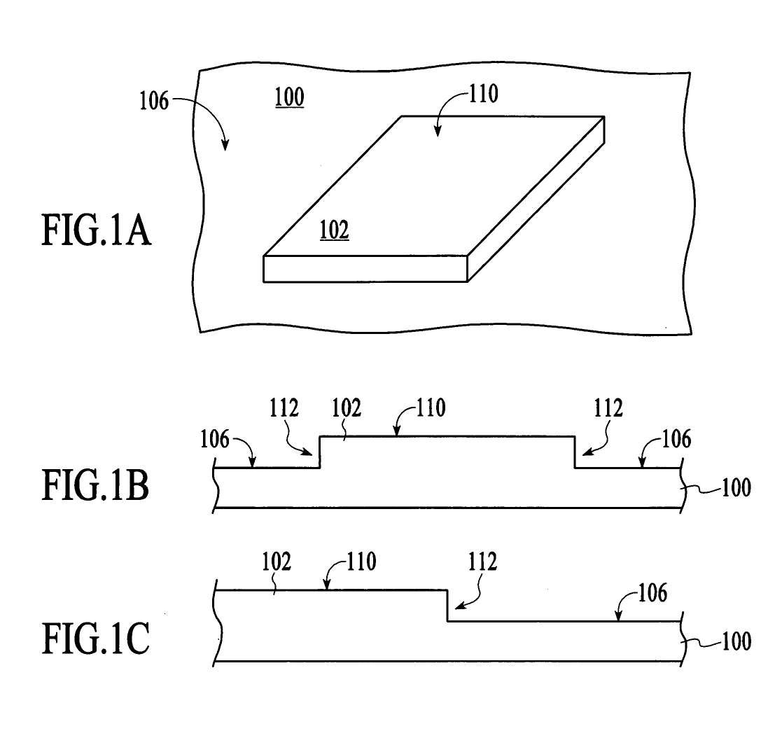

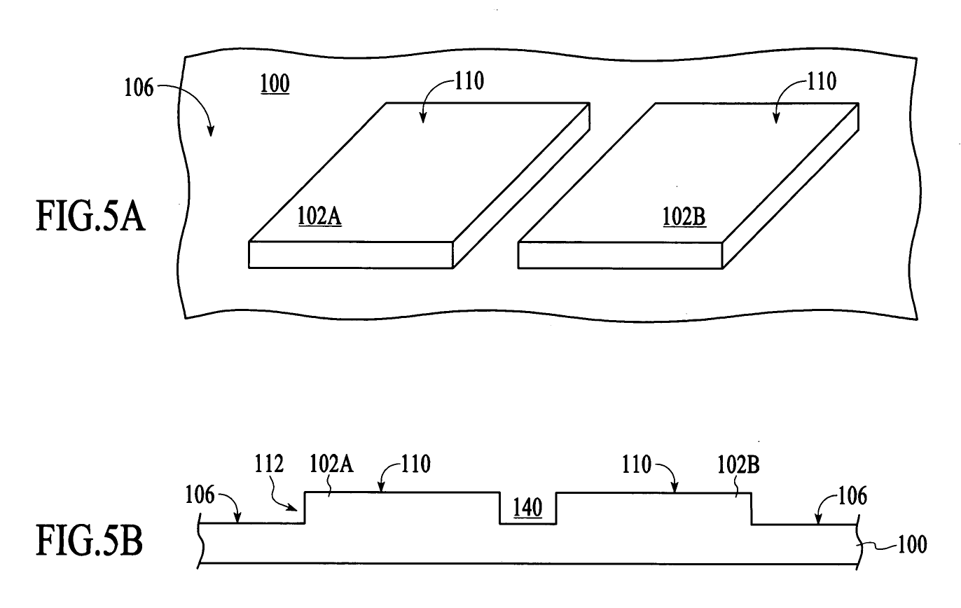

Producing a nanostructure, such as a nano-scale cantilever or a nanobridge, involves forming an elevational discontinuity, the elevational discontinuity having an upper surface and a lower surface, growing a nanowire that extends from the upper surface, and then changing the orientation of the nanowire such that a portion of the nanowire extends above the lower surface. The orientation of the nanowire can be changed by exposing the nanowire to a flux of ions. An exemplary method for producing a nano-scale cantilever in accordance with the invention is described with reference to FIGS. 1A-4C. An exemplary method for producing a nano-scale bridge structure in accordance with the invention is described with reference to FIGS. 5A-8C.

In a first operation, a protruding structure is formed on a substrate to provide an elevational discontinuity. FIG. 1A is a perspective view of a substrate 100 that includes a protruding structure 102 and FIG. 1B is a side view of FIG. 1A. In an embodiment, the substrate is a single-crystalline silicon wafer and the protruding structure is formed at a major surface 106 of the substrate using conventional lithography and etching processes. For example, the protruding structure is formed by placing a mask over the area of the protruding structure and etching away a portion of the substrate around the protruding structure to produce an elevated “island.” The elevation difference between the surface 110 of the protruding structure and the major surface 106 can be, for example, on the order of 10 μm. In an alternative embodiment, the protruding structure is formed by growing an additional layer on the substrate and etching portions of the additional layer to leave the protruding structure. Further, a combination of growing and etching can be used to form the protruding structure. The particular technique used to produce the protruding structure is not critical.

In the example of FIGS. 1A and 1B, the elevational discontinuity is provided by the protruding structure 102, which is formed as an island on the substrate 100. In other embodiments the elevational discontinuity is provided by a single elevational discontinuity at the surface of the substance. For example, a single step between an upper surface and a lower surface of the substrate can provide the elevational discontinuity. FIG. 1C is a side view of substrate 100 in which the elevational discontinuity is provided by a single step 112 between an upper surface 110 and a lower surface 106 of the substrate. As will be seen below, the purpose of the elevational discontinuity is to allow a portion of a nanowire to exist in free space. The particular form of the elevational discontinuity and the technique used to produce the elevational discontinuity is not critical. The point of an abrupt elevational discontinuity, such as a step between an upper surface and a lower surface, is referred to herein as an “edge.” As used herein, “elevational” or “elevation” refers to a distance in a direction orthogonal to a point or a major surface of the substrate and “upper” and “lower” are relative terms in which “upper” refers to a greater elevation than “lower.”

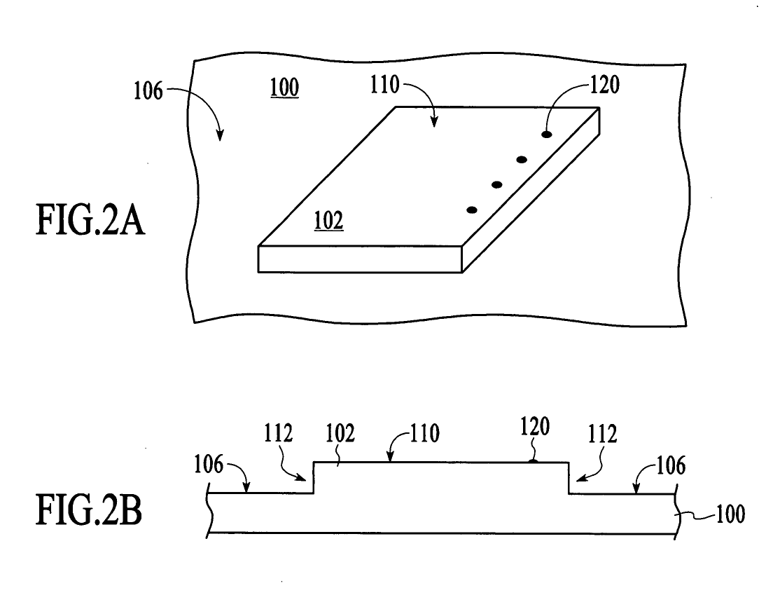

In a next operation, catalyst nanoparticles are deposited on the upper surface of the protruding structure. In an embodiment, the catalyst nanoparticles are deposited on the upper surface of the protruding structure near an edge of the 30 protruding structure. FIG. 2A is a perspective view of catalyst nanoparticles 120 deposited on the surface 110 of the protruding structure 102 near an edge 112 and FIG. 2B is a side view of FIG. 2A. The catalyst nanoparticles may be metal catalyst nanoparticles such as gold catalyst nanoparticles, which are deposited on the upper surface 110 of the protruding structure using, for example, a process of electron-beam lithography, metal deposition, and lift-off. As is known in the field, the size and location of the catalyst nanoparticles can be controlled through electron-beam lithography and metal deposition processes. Other techniques for depositing the catalyst nanoparticles, such as nanoimprint lithography, can be used. As will become clear below, the catalyst nanoparticles should be located near enough to an edge of the protruding structure that a portion of each nanowire extends beyond the edge of the protruding structure once the orientation of the nanowires is changed.

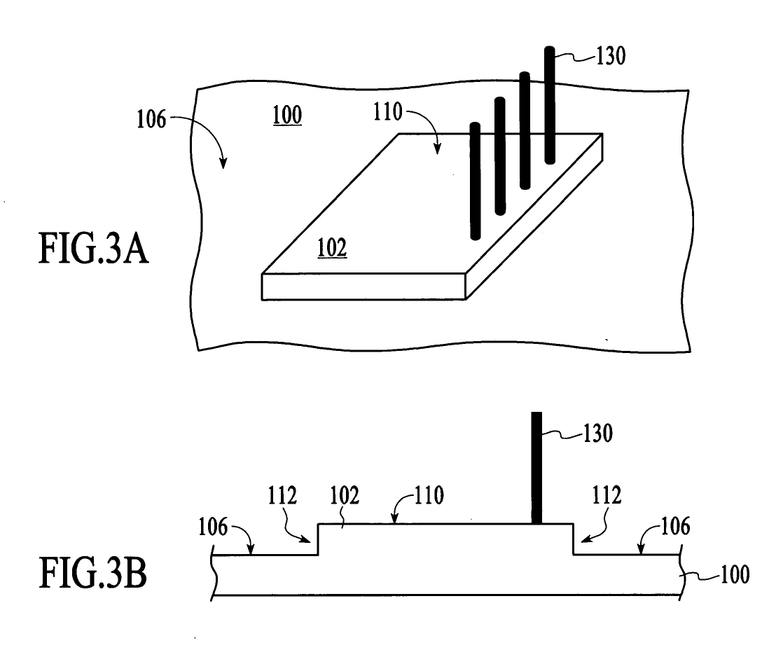

In a next operation, nanowires are grown extending from the protruding structure. FIG. 3A is a perspective view of nanowires 130 that have been grown orthogonal to the major surface 106 of the substrate 100. FIG. 3B is a side view of FIG. 3A. In the embodiment of FIGS. 3A and 3B, the nanowires are elongated semiconductor structures that have at least one dimension (e.g., a diameter dimension) in the nano-scale range of approximately 1-100 nm. As shown in FIG. 3A, multiple nanowires are grown simultaneously to form an array of parallel nanowires.

The nanowires 130 can be grown using various different techniques. In one embodiment, the nanowires are grown at the locations of the catalyst nanoparticles 120 using a vapor-liquid-solid (VLS) growth process. VLS growth processes are well-known in the field of nanowire growth. A typical VLS process involves the catalytic decomposition of gaseous precursors on the surface of the catalyst nanoparticles and the subsequent nucleation and growth of single-crystalline nanowires. The diameters of the nanowires are proportional to the size of the catalyst nanoparticles. By controlling the size of the catalyst nanoparticles and the growth time, nanowires with desired diameters and lengths can be grown. In an embodiment, nanowires with diameters on the order of 1-100 nm and lengths of less than 10 μm are grown.

As is known in the field, nanowires have preferred growth directions. For example, silicon and III-V compound semiconductor nanowires prefer to grow along the <111> direction. Nanowires that extend orthogonal to the major surface of the substrate can be grown by selecting proper substrates and controlling growth conditions. In an embodiment, a <111> silicon wafer is used as the substrate and silicon and III-V compound semiconductor nanowires are grown epitaxially. In an embodiment, the nanowires are formed of ZnO. In the embodiment described herein, the nanowires grow orthogonal to the major surface of the substrate and orthogonal to the upper surface of the protruding structure, although in other embodiments, the nanowires simply grow such that they extend from the upper surface of the protruding structure. As used herein, the term “orthogonal” is defined to include substantially orthogonal, for example, within ±10 degrees from exactly orthogonal.

In some nano-scale cantilever applications, it is desirable to grow nanowires with uniform cross-sectional area. A technique for growing nanowires with uniform cross-sectional area is described in U.S. patent application Ser. No. 10/857,191, entitled “Method of Growing Semiconductor Nanowires with Uniform Cross-Sectional Area Using Chemical Vapor Deposition,” filed May 28, 2004, which is assigned to the assignee of the current invention and incorporated by reference herein.

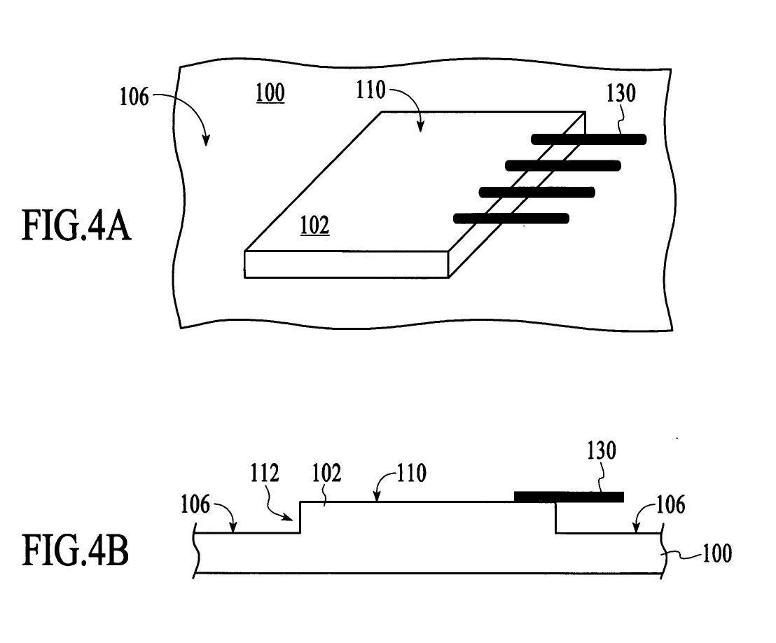

In a next operation, the orientation of the nanowires is changed such that a portion of each nanowire extends beyond the edge of the protruding structure. In the case where the nanowires are initially orthogonal to the major surface of the substrate, the orientation of the nanowires is changed from being orthogonal to the major surface of the substrate to being parallel to the major surface of the substrate. FIG. 4A is a perspective view of the nanowires 130 of FIG. 3A after the orientation of the nanowires has been changed from orthogonal to the major surface 106 of the substrate 100 to parallel to the major surface of the substrate. FIG. 4B is a side view of FIG. 4A. As depicted in FIGS. 4A and 4B, a portion of each nanowire extends beyond the edge 112 of the protruding structure 102 and above the major surface 106 of the substrate, thereby forming a nano-scale cantilever. How far the nanowires extend beyond the edge of the protruding structure is a function of the location of the catalyst nanoparticles 120 and the length of the nanowires. As used herein, the term “parallel” is defined to include substantially parallel, for example, within ±10 degrees from exactly parallel.

In an embodiment, the orientation of the nanowires 130 is changed by exposing the nanowires to a flux of ions. For example, the nanowires are exposed to argon ions at an ion energy of approximately 5 keV and an integrated flux density of about 6×10¹⁵ ions/cm². Using the flux of ions enables the nanowires to be re-oriented without force being applied through physical contact from another structure. An exemplary technique for changing the orientation of nanowires using a flux of ions is described in U.S. Pat. No. 6,248,674, entitled “Method of Aligning Nanowires,” which is incorporated by reference herein.

Alternative nanostructures, such as a nanobridge structure, can be produced using a technique that is similar to the technique described above with reference to FIGS. 1A-4B. An embodiment of a method for forming a nanobridge is described with reference to FIGS. 5A-8B.

In a first operation, two protruding structures are formed adjacent to each other on the major surface of a substrate such that the two protruding structures collectively define a trench. FIGS. 5A and 5B depict two protruding structures 102A and 102B that are formed as described above with reference to FIGS. 1A and 1B. The two protruding structures collectively define a trench 140.

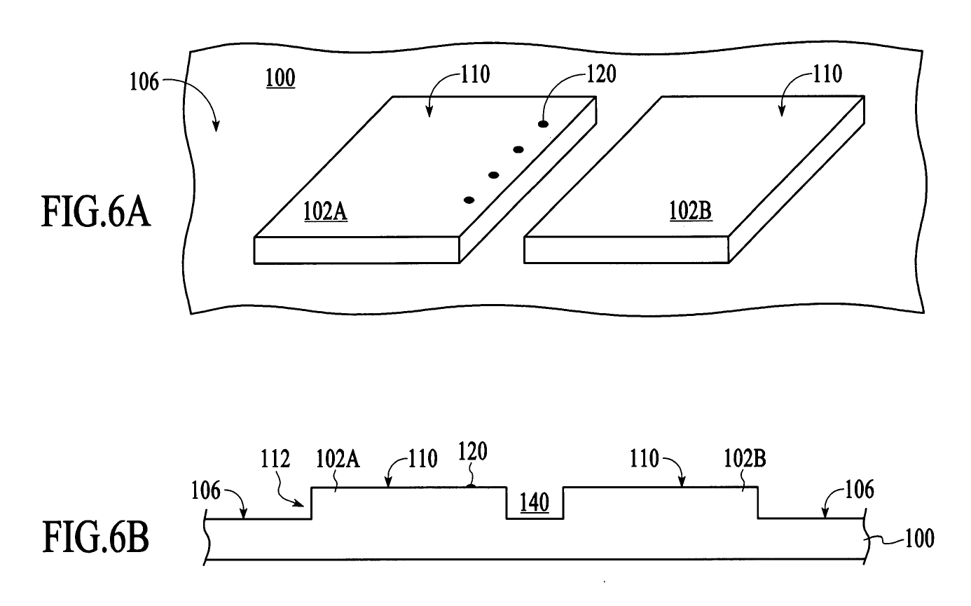

In a next operation, catalyst nanoparticles are deposited on the upper surface of one of the protruding structures. FIGS. 6A and 6B depict catalyst nanoparticles 120 formed on the upper surface of one of the protruding structures 102A and 102B as described above with reference to FIGS. 2A and 2B.

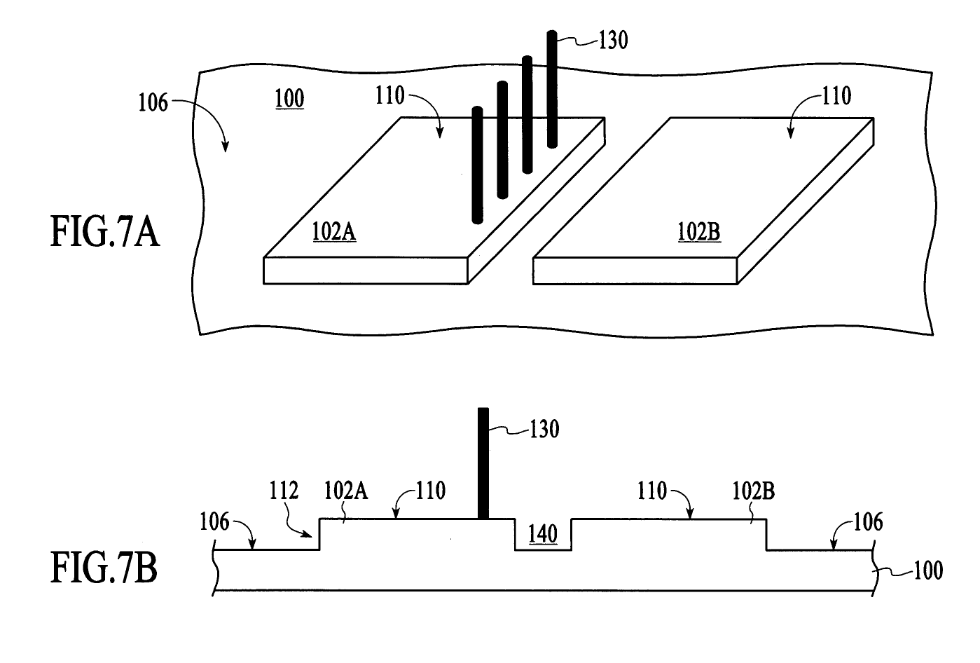

In a next operation, nanowires are grown at the locations of the catalyst nanoparticles. FIGS. 7A and 7B depict nanowires 130 grown at the locations of the catalyst nanoparticles 120 as described above with reference to FIGS. 3A and 3B. As depicted in FIGS. 7A and 7B, the nanowires are orthogonal to the major surface 106 of the substrate 100 and are long enough to span the trench 140 between the two protruding structures 102A and 102B.

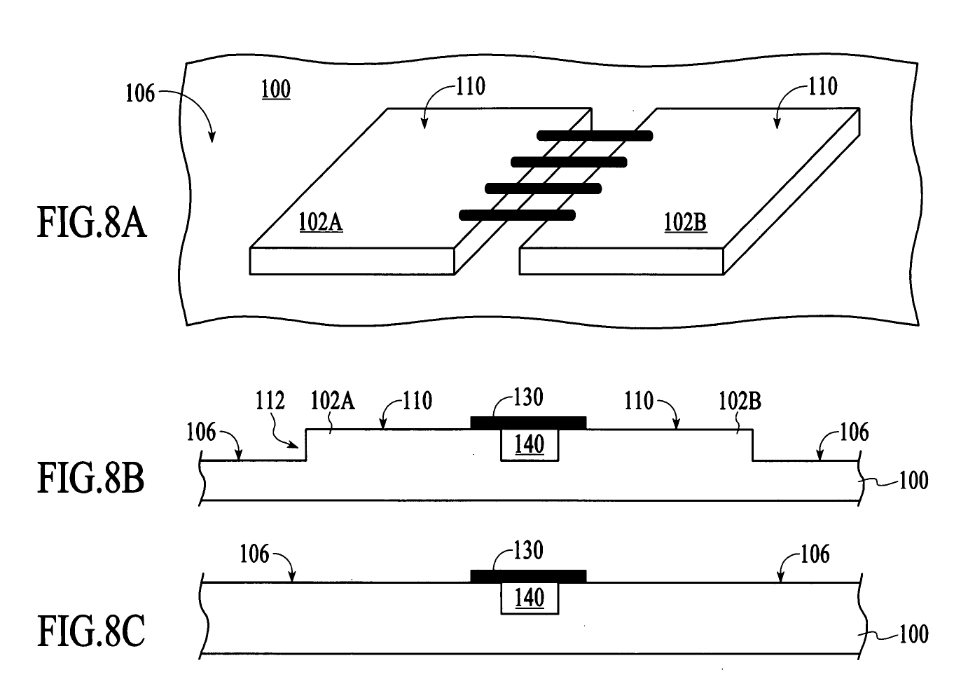

In a next operation, the orientation of the nanowires is changed such that the nanowires are parallel to the major surface of the substrate. As a result of the changed orientation, the nanowires span the trench between the two protruding structures. In particular, the nanowires are supported above the trench by both of the protruding structures. FIGS. 8A and 8B depict the nanowires 130 spanning the trench 140 between the two protruding structures 102A and 102B.

In an alternative to the method described with reference to FIGS. 5A-8B, a trench is formed by etching a trench into the substrate instead of by forming two separate protruding islands on the substrate. FIG. 8C is a side view of substrate 100 in which trench 140 is formed by trenching below the major surface of the substrate and in which nanowires 130 are re-oriented to span the trench. Other techniques for forming the trench are possible.

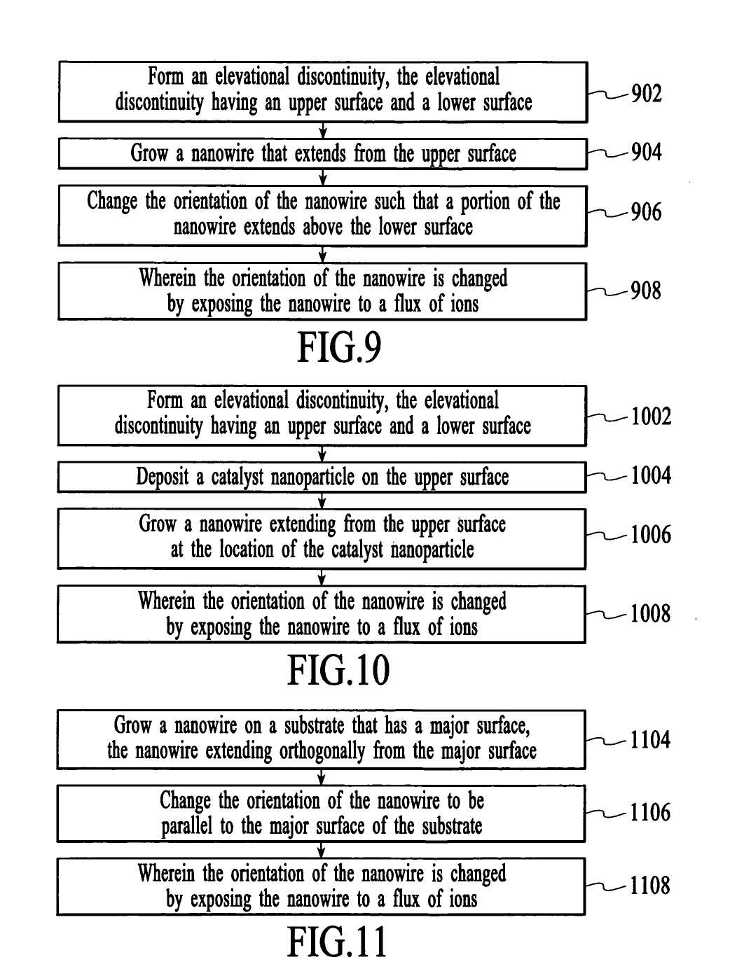

FIG. 9 is a process flow diagram of a method for producing a nanostructure. At block 902, an elevational discontinuity is formed, the elevational discontinuity having an upper surface and a lower surface. At block 904, a nanowire that extends from the upper surface is grown. At block 906, the orientation of the nanowire is changed such that a portion of the nanowire extends above the lower surface. In an embodiment, the orientation of the nanowire is changed by exposing the nanowire to a flux of ions, block 908.

FIG. 10 is a process flow diagram of another method for producing a nanostructure. At block 1002, an elevational discontinuity is formed, the elevational discontinuity having an upper surface and a lower surface. At block 1003, a catalyst nanoparticle is deposited on the upper surface. At block 1004, a nanowire is grown extending from the upper surface at the location of the catalyst nanoparticle. At block 1006, the orientation of the nanowire is changed such that a portion of the nanowire extends above the lower surface. In an embodiment, the orientation of the nanowire is changed by exposing the nanowire to a flux of ions, block 1008.

FIG. 11 is a process flow diagram of another method for producing a nanostructure. At block 1104, a nanowire is grown on a substrate that has a major surface, the nanowire extending orthogonally from the major surface. At block 1106, the orientation of the nanowire is changed to be parallel to the major surface of the substrate. In an embodiment, the orientation of the nanowire is changed by exposing the nanowire to a flux of ions, block 1108.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A method for producing a nanostructure, the method comprising:
forming an elevational discontinuity, the elevational discontinuity comprising an upper surface and a lower surface;
growing a nanowire that extends from the upper surface; and
changing the orientation of the nanowire such that a portion of the nanowire extends above the lower surface.

2. The method of claim 1 wherein changing the orientation of the nanowire comprises exposing the nanowire to a flux of ions.

3. The method of claim 1 wherein the nanowire is grown orthogonally to the upper surface.

4. The method of claim 3 wherein the orientation of the nanowire is changed from orthogonal to the upper surface to parallel to the upper surface.

5. The method of claim 4 wherein growing the nanowire comprises growing the nanowire near an edge of the elevational discontinuity.

6. The method of claim 1 further including initially forming another elevational discontinuity such that the two elevational discontinuities collectively define a trench, and wherein the orientation of the nanowire is changed such that the nanowire spans the trench between the two elevational discontinuities.

7. The method of claim 1 wherein the elevational discontinuity is formed as a trench in a substrate, and wherein the orientation of the nanowire is changed such that the nanowire spans the trench.

8. A method for producing a nanostructure, the method comprising:
forming an elevational discontinuity, the elevational discontinuity comprising an upper surface and a lower surface;
depositing a catalyst nanoparticle on the upper surface;
growing a nanowire extending from the upper surface at the location of the catalyst nanoparticle; and
changing the orientation of the nanowire such that a portion of the nanowire extends above the lower surface.

9. The method of claim 8 wherein changing the orientation of the nanowire comprises exposing the nanowire to a flux of ions.

10. The method of claim 8 wherein the catalyst nanoparticle is deposited on the upper surface near an edge of the elevational discontinuity.

11. The method of claim 8 wherein the nanowire is grown in a direction that is orthogonal to the upper surface.

12. The method of claim 11 wherein the orientation of the nanowire is changed from orthogonal to the upper surface to parallel to the upper surface.

13. The method of claim 8 further including forming a second elevational discontinuity adjacent to the elevational discontinuity such that the two elevational discontinuities collectively define a trench, and wherein the orientation of the nanowire is changed such that the nanowire spans the trench between the two elevational discontinuities.

14. A method for producing a nanostructure, the method comprising:
growing a nanowire on a substrate that has a major surface, the nanowire extending orthogonally from the major surface; and
changing the orientation of the nanowire to be parallel to the major surface of the substrate.

15. The method of claim 14 wherein changing the orientation of the nanowire comprises exposing the nanowire to a flux of ions.

16. The method of claim 14 in which the substrate comprises an elevational discontinuity and the growing comprises growing the nanowire on an upper surface of the elevational discontinuity.

17. The method of claim 16 wherein growing the nanowire comprises depositing a catalyst nanoparticle on the upper surface near an edge of the elevational discontinuity.

18. The method of claim 17 wherein the location of the catalyst nanoparticle and the length of the nanowire are such that a portion of the nanowire extends beyond the edge of the elevational discontinuity after the orientation is changed from orthogonal to parallel.

19. The method of claim 18 wherein changing the orientation of the nanowire comprises exposing the nanowire to a flux of ions.

20. The method of claim 14 wherein the nanowire comprises a semiconductor material.
